(19) United States
(12) Patent Application Publication
(10) Pub. No.: US 2024/0402006 A1
(43) Pub. Date: Dec. 5, 2024

(54) FLEXIBLE ULTRAVIOLET SENSOR

(71) Applicant: International Business Machines Corporation, Armonk, NY (US)

(72) Inventors: Jeremy R. Fox, Georgetown, TX (US); Martin G. Keen, Cary, NC (US); Alexander Reznicek, Troy, NY (US); Bahman Hekmatshoartabari, White Plains, NY (US)

(21) Appl. No.: 18/328,331

(22) Filed: Jun. 2, 2023

(51) Int. Cl. G01J 1/42; H01L 27/142; H01L 31/0376; H01L 31/0392; H01L 31/0445; H01L 31/113

(52) U.S. Cl. CPC G01J 1/429; H01L 27/142; H01L 31/03762; H01L 31/03926; H01L 31/0445; H01L 31/1136; G02B 26/005; G02F 1/13312; G02F 1/167; G02F 1/1685; G02F 2203/02

(57) ABSTRACT

A flexible ultraviolet sensor circuit is provided comprising a number of solar cells, a reflective display device electrically connected to the solar cells, and a floating gate transistor electrically connected to the solar cells and reflective display device. A floating gate in the floating gate transistor discharges in response to ultraviolet light such that the floating gate transistor turns on when a threshold voltage of the floating gate transistor drops below a combined open circuit voltage of the solar cells minus a switching threshold of the reflective display device, thereby causing electrical current flow through the ultraviolet sensor circuit. The reflective display device changes as the electrical current flow increases, indicating total ultraviolet light exposure.

### BACKGROUND

The present disclosure relates generally to photosensitive devices, and more specifically to a flexible thin-film ultraviolet monitor device that generates electrical current through a circuit proportional to ultraviolet light exposure.

Health risks associated with ultraviolet light have prompted the need to reliably detect total ultraviolet exposure. Such detection methods might include passive devices that rely on photochemical reactions to indicate ultraviolet exposure. Other detection methods include active devices that employ photodiodes sensitive to ultraviolet radiation to generate an indicator signal.

### SUMMARY

An illustrative embodiment provides a flexible ultraviolet sensor circuit comprising a number of solar cells, a reflective display device electrically connected to the solar cells, and a floating gate transistor electrically connected to the solar cells and reflective display device. A floating gate in the floating gate transistor discharges in response to ultraviolet light such that the floating gate transistor turns on when a threshold voltage of the floating gate transistor drops below a combined open circuit voltage of the solar cells minus a switching threshold of the reflective display device, thereby causing electrical current flow through the ultraviolet sensor circuit. The reflective display device changes as the electrical current flow increases, indicating total ultraviolet light exposure. According to other illustrative embodiments, a method for detecting cumulative ultraviolet light exposure is provided.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 depicts a block diagram for a flexible ultraviolet sensor in accordance with an illustrative embodiment;

FIG. 2 depicts a circuit diagram of an ultraviolet sensor circuit in accordance with an illustrative embodiment;

FIG. 3 is a cross-section diagram of a flexible ultraviolet sensor in accordance with an illustrative embodiment;

FIG. 4 is a cross-section diagram of a flexible ultraviolet sensor with top and bottom P-I-N solar cells in accordance with an illustrative embodiment;

FIG. 5 is a cross-section diagram of a flexible ultraviolet sensor with an inverted-staggered bottom-gate thin-film transistor in accordance with an illustrative embodiment;

FIG. 6 is a cross-section diagram of a flexible ultraviolet sensor with a floating gate region used for charge trapping in accordance with an illustrative embodiment;

FIG. 7 is a cross-section diagram of a flexible ultraviolet sensor with series connected solar cells in accordance with an illustrative embodiment; and

FIG. 8 is a cross-section diagram of a flexible ultraviolet sensor in accordance with an alternate illustrative embodiment.

### DETAILED DESCRIPTION

The illustrative embodiments recognize and take into account that rising rates of skin cancer present a need for ultraviolet (UV) light monitors that are reliable, widely accessible, and convenient to use. Existing ultraviolet monitors fall into two general categories. The first category includes passive monitors, which typically include a coating comprising a chemical compound that changes color under ultraviolet light due to photochemical reactions. The second category includes active monitors that comprise a silicon photodiode and complementary metal-oxide semiconductor (CMOS) circuitry for readout of the photodiode current and/or transmission.

The illustrative embodiments also recognize and take into account that the passive monitors are generally not reliable, and the active monitors are generally not convenient to use due to their footprint and/or required operating conditions.

The illustrative embodiments provide an active ultraviolet light monitor that can be implemented in small footprints on lightweight flexible plastic substrates. The ultraviolet monitor can be fabricated with low-cost thin-film device methods at low temperatures and can be used as a disposable patch. This patch might be placed, for example, on a user's fingernail or skin. The ultraviolet monitor employs a charged floating gate that discharges in response to ultraviolet exposure, generating current flow through a circuit.

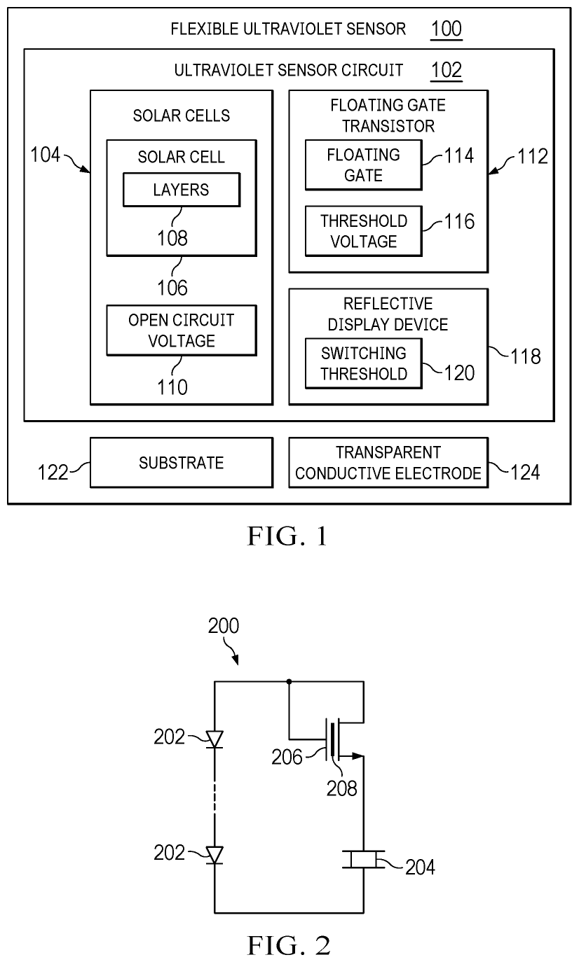

FIG. 1 depicts a block diagram for a flexible ultraviolet sensor in accordance with an illustrative embodiment. Flexible ultraviolet sensor 100 comprises an ultraviolet sensor circuit 102, which is located between bottom substrate 122 and an upper transparent conductive electrode 124. Ultraviolet sensor circuit 102 comprises a number of solar cells 104, a floating gate transistor 112, and a reflective display device 118 electrically connected to each other. The upper transparent conductive electrode 124 may also serve as a transparent conductive electrode for the reflective display device 118.

Solar cells 104 might comprise thin-film solar cells. Each solar cell 106 might comprise a number of layers 108, which might include differently doped semiconductor regions forming, e.g., P-I-N solar cell. A P-I-N solar cell comprises three regions of semiconductor material: a P-type doped region, a lightly doped intrinsic (I) region, and an N-type doped region. The intrinsic I region separates the P-type region and N-type region.

Solar cells 104 might comprise at least one of silicon, silicon-germanium, or silicon-carbide, each having an amorphous, nanocrystalline, microcrystalline, or polycrystalline structure. Solar cells 104 might also comprise at least one of metal-oxide, organic, or perovskite semiconductor or a compound semiconductor material such as, e.g., copper zinc tin sulfide (CZTS) or copper indium gallium diselenide (CIGS).

The solar cells 104 are connected in series and have an open circuit voltage 110.

Floating gate transistor 112 includes floating gate 114 and is charged to reach a certain threshold voltage 116. Floating gate transistor 112 might comprise a thin-film floating gate transistor and can be made of at least one of, e.g., amorphous silicon, nano-crystalline silicon, low-temperature poly-silicon (LTPS), amorphous metal oxide, organic, amorphous-silicon/LTPS heterojunction, or organic/LTPS heterojunction.

Reflective display device 118 might comprise a thin-film reflective display device such as, e.g., an electrophoretic display, a cholesteric display, or an electrowetting display. Reflective display device 118 has a switching threshold 120, which is the minimum voltage bias required for the reflective display device 118 to switch (i.e., transition) from an OFF state to an ON state, or vice versa. In an embodiment, reflective display device 118 is OFF by default (i.e., OFF in the absence of a voltage bias), and the switching threshold 120 corresponds to the onset of the display's ON state.

FIG. 2 depicts a circuit diagram of an ultraviolet sensor circuit in accordance with an illustrative embodiment. Ultraviolet sensor circuit 200 is an example of ultraviolet sensor circuit 102 in FIG. 1.

After manufacture of the ultraviolet sensor circuit 200, the floating gate 208 is charged by applying a voltage between the control gate and source. This charging results in a threshold voltage V_{T} of the floating gate transistor 206 that is larger than the combined open circuit voltage V_{OC} of the solar cells 202 minus the switching threshold V_{S} of the reflective display device 204 (V_{T}>V_{OC}−V_{S}). Note that the combined open circuit voltage of the solar cells 202 connected in series is the sum of the open circuit voltages of the individual solar cells.

The current-voltage (I-V) characteristics of the diode-connected floating gate transistor 206 can be expressed as:

$$I = {K ( V - {V}_{T} )}^{2}$$

where I is the current flowing through the diode-connected floating-gate transistor 206, K is the transconductance parameter of the floating-gate transistor 206, and V is the voltage drop across the diode-connected floating-gate transistor 206.

The change in the threshold circuit V_{T} of the floating gate transistor 206 can be expressed as:

$$Δ {V}_{T} = Δ {Q}_{T} / {C}_{FG}$$

where Q_{T} is trapped charge in the floating gate 208 and C_{FG} is the effective capacitance of the floating gate 208. The change in Q_{T} is expressed as:

ΔQ_{T}∝UV dose
where

$$UV dose = UV intensity \times exposure time$$

The floating gate 208 discharges in response to ultraviolet light exposure such that the floating gate transistor turns on when the threshold voltage of the floating gate transistor drops below the combined open-circuit voltage of the solar cells minus the switching threshold of the reflective display device (V_{T}<V_{OC}−V_{S}), which causes electrical current flow through the ultraviolet sensor circuit 200. The reflective display device 204 changes as the electrical current flow increases, indicating total ultraviolet light exposure. The reflective display 204 might change in brightness and/or color according to the total ultraviolet light exposure, thereby indicating the level of ultraviolet dose.

The solar cells 202 and floating gate transistor 206 can be fabricated with low-cost, large-area technologies in flexible substrates including, but not limited to, amorphous silicon, low-temperature polysilicon, organic, metal oxide, etc. Reflective display device 204 might include, but is not limited to, liquid crystal, electronic ink (electrophoretic), cholesteric, electro-wetting, etc.

It will be appreciated that, while flexible circuit components (namely, solar cells 202, a floating-gate transistor 206, and a reflective display 204, according to the sensor circuit 200) and a flexible substrate are required for enabling a flexible ultraviolet sensor which is of particular interest as a wearable device, a rigid (non-flexible) ultraviolet sensor can also be implemented according to the sensor circuit 200 wherein at least one of the circuit components and/or the substrate are not mechanically flexible. It will be further appreciated that, while reflective displays are particularly suited for use in the described ultraviolet sensors due to advantages such as low power-consumption and good readability under sunlight, other types of displays may also be used.

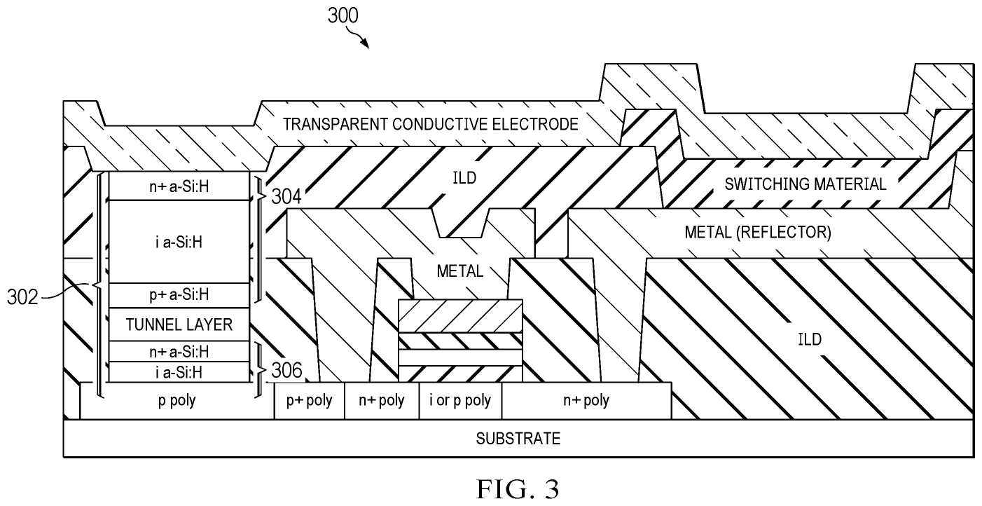

FIG. 3 is a cross-section diagram of a flexible ultraviolet sensor in accordance with an illustrative embodiment. In this embodiment, flexible ultraviolet sensor 300 comprises a tandem double-junction solar cell 302 with a P-I-N a-Si:H (hydrogenated amorphous silicon) top cell 304 and a-Si:H/poly-Si heterojunction solar cell as the bottom cell 306. Poly-Si can be prepared with an excimer laser at low temperatures (i.e., room temperature) on flexible plastic substrates.

It should be noted that dual or triple junction solar cells can also be formed on top of the heterojunction bottom cell 306 to create a triple or quadruple junction embodiment of solar cell 302.

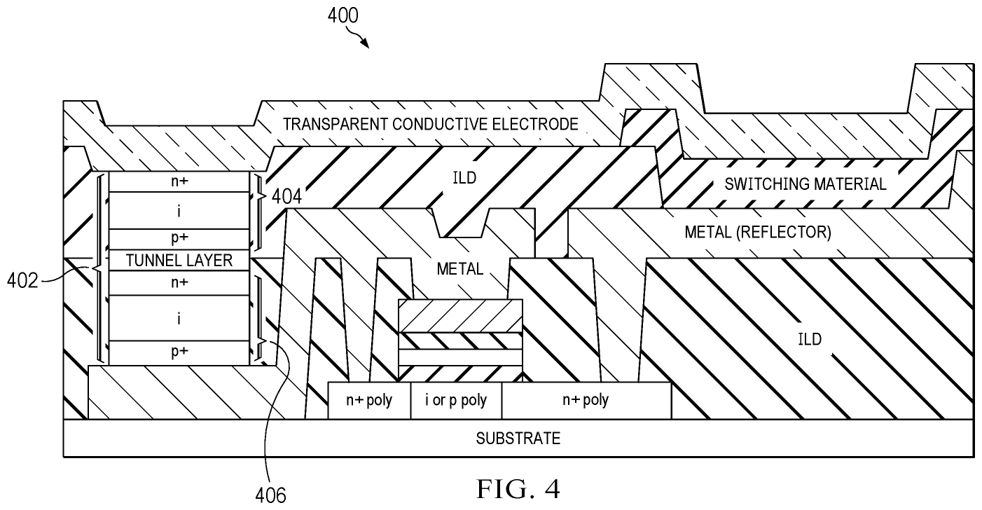

FIG. 4 is a cross-section diagram of a flexible ultraviolet sensor in accordance with an alternate illustrative embodiment. In this embodiment, flexible ultraviolet sensor 400 is similar to flexible ultraviolet sensor 300 except both the top cell 404 and bottom cell 406 of solar cell 402 are P-I-N cells.

In one example, the top cell 404 is based on a-Si:H and/or a-SiC:H (hydrogenated amorphous silicon-carbide), and the bottom cell 406 is based on a-SiGe:H (hydrogenated amorphous silicon-germanium) or nc-Si:H (hydrogenated nanocrystalline silicon). Typically, the material of the top cell 404 has a wider bandgap than the bottom cell 406.

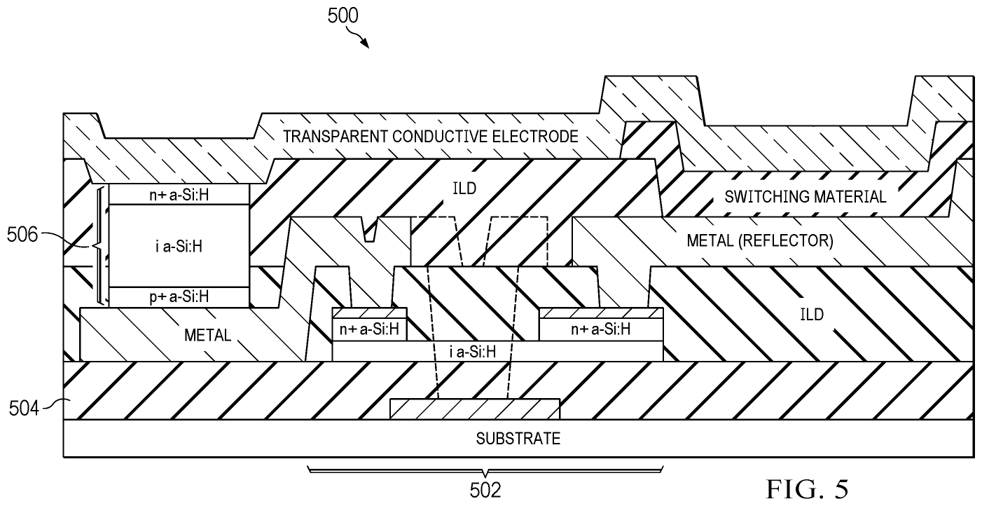

FIG. 5 is a cross-section diagram of a flexible ultraviolet sensor in accordance with an alternate illustrative embodiment. In this embodiment, flexible ultraviolet sensor 500 comprises an inverted-staggered bottom-gate a-Si:H thin-film transistor 502. Charge trapping interface 504 functions as a floating gate and can be created by intentional reactive ion etching (RIE) damage in nitride. Possible charge trapping structures include nitride, oxide, and nitride gate dielectric.

A simple P-I-N solar cell 506 is shown in FIG. 5. However, various solar cell structures such as the example described above can be used.

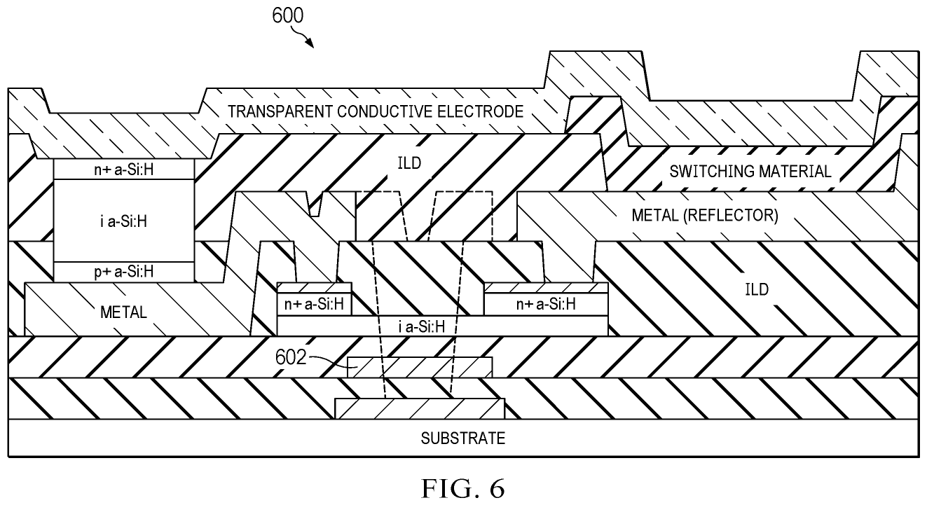

FIG. 6 is a cross-section diagram of a flexible ultraviolet sensor in accordance with an alternate illustrative embodiment. In this embodiment, flexible ultraviolet sensor 600 is similar to flexible ultraviolet sensor 500 except that a floating gate region 602 is used for charge trapping. Similar to the embodiments described above, floating gate region 602 can be comprised of a conductive material such a metal or any structure that can trap charge including dielectrics, and dielectrics that include quantum dot structures.

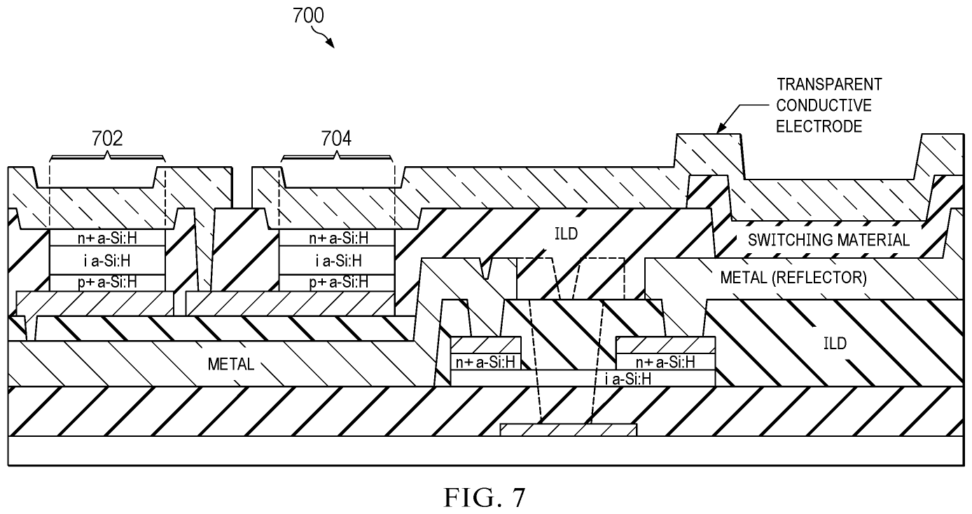

FIG. 7 is a cross-section diagram of a flexible ultraviolet sensor in accordance with an alternate illustrative embodiment. In this embodiment, flexible ultraviolet sensor 700 is similar to flexible ultraviolet sensor 500 but with two P-I-N solar cells 702, 704 connected in series. It should be noted that series connections of solar cells can also be used in any of the embodiments described above.

Other variations possible with any of the embodiments of the flexible ultraviolet sensor described above include the use of organic transistors and organic solar cells as well as metal-oxide transistors.

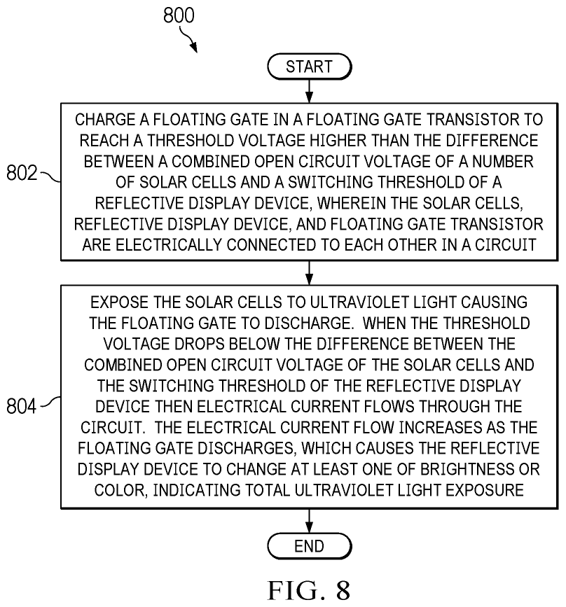

FIG. 8 depicts a flowchart of a process for detecting cumulative ultraviolet light exposure in accordance with an illustrative embodiment. Process in 800 can be implemented in flexible ultraviolet sensor shown in FIGS. 1-7.

Process 800 begins by charging a floating gate in a floating gate transistor to reach a threshold voltage higher than the difference between a combined open circuit voltage of a number of solar cells and a switching threshold of a reflective display device, wherein the solar cells, reflective display device, and floating gate transistor are electrically connected to each other in a circuit (step 802).

The solar cells are exposed to ultraviolet light causing the floating gate to discharge. When the threshold voltage drops below the difference between the combined open circuit voltage of the solar cells and the switching threshold of the reflective display device then electrical current flows through the circuit. The electrical current flow increases as the floating gate discharges, which causes the reflective display device to change at least one of brightness or color, indicating total ultraviolet light exposure (step 804). Process 800 then ends.

As used herein, a “number of,” when used with reference to objects, means one or more objects. For example, a “number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

As used herein, a “computer instruction,” or “computer program”, means one step or a set of steps that includes information on how to operate, perform, or maintain particular computer software or hardware. For example, a “computer instruction” can be a computer program instruction in the form of lines of code or source code that are executable by a computer system.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

The descriptions of the various embodiments of the present invention have been presented for purposes of illustration but are not intended to be exhaustive or limited to the embodiments disclosed. Not all embodiments will include all of the features described in the illustrative examples. Further, different illustrative embodiments may provide different features as compared to other illustrative embodiments. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. An ultraviolet sensor circuit, comprising:
a number of solar cells;
a reflective display device electrically connected to the solar cells; and
a floating gate transistor electrically connected to the solar cells and reflective display device, wherein a floating gate in the floating gate transistor discharges in response to ultraviolet light such that the floating gate transistor turns on when a threshold voltage of the floating gate transistor drops below a combined open circuit voltage of the solar cells minus a switching threshold of the reflective display device, thereby causing electrical current flow through the ultraviolet sensor circuit, and wherein the reflective display device changes as the electrical current flow increases, indicating total ultraviolet light exposure.

2. The ultraviolet sensor circuit of claim 1, wherein the reflective display device changes in brightness according to the total ultraviolet light exposure.

3. The ultraviolet sensor circuit of claim 1, wherein the reflective display device changes color according to the total ultraviolet light exposure.

4. The ultraviolet sensor circuit of claim 1, wherein the solar cells comprise thin-film solar cells.

5. The ultraviolet sensor circuit of claim 1, wherein the floating gate transistor comprises a thin-film floating gate transistor.

6. The ultraviolet sensor circuit of claim 1, wherein the reflective display device comprises a thin-film reflective display device.

7. The ultraviolet sensor circuit of claim 1, wherein the solar cells comprise at least one of:
amorphous, nanocrystalline, microcrystalline, or polycrystalline silicon;
amorphous, nanocrystalline, microcrystalline, or polycrystalline silicon-germanium; or
amorphous, nanocrystalline, microcrystalline, or polycrystalline silicon-carbide.

8. The ultraviolet sensor circuit of claim 1, wherein the solar cells comprise at least one of:
metal-oxide, organic, or perovskite semiconductor; or
copper zinc tin sulfide (CZTS); or
copper indium gallium diselenide (CIGS).

9. The ultraviolet sensor circuit of claim 1, wherein the reflective display device comprises one of:
an electrophoretic display;
a cholesteric display; or
an electrowetting display.

10. The ultraviolet sensor circuit of claim 1, wherein the floating gate transistor comprises one of:
amorphous silicon;
nano-crystalline silicon;
low-temperature poly-silicon (LTPS);
amorphous metal oxide;
organic, amorphous-silicon/LTPS heterojunction; or
organic/LTPS heterojunction.

11. The ultraviolet sensor circuit of claim 1, wherein the solar cells are connected in series.

12. A flexible ultraviolet light sensor, comprising:
a number of solar cells having a combined open circuit voltage;
a reflective display device having a switching threshold;
a floating gate transistor, wherein the solar cells, reflective display device, and a floating gate transistor are electrically connected to each other in a circuit, and wherein a floating gate in the floating gate transistor discharges in response to exposure of the solar cells to ultraviolet light such that the floating gate transistor turns on when a threshold voltage of the gloating gate transistor drops below the difference between the combined open circuit voltage and switching threshold, and wherein the reflective display device changes as the electrical current increases with accumulating ultraviolet light exposure;
a substrate underlying the solar cells, reflective display device, and floating gate transistor; and
a transparent conductive electrode overlaying the solar cells, reflective display device, and floating gate transistor.

13. The flexible ultraviolet light sensor of claim 12, wherein:
the solar cells comprise thin-film solar cells;
the floating gate transistor comprises a thin-film floating gate transistor; and
the reflective display device comprises a thin-film reflective display device.

14. The flexible ultraviolet light sensor of claim 12, wherein the reflective display device changes in at least one of the following:
brightness; or
color.

15. The flexible ultraviolet light sensor of claim 12, wherein the solar cells comprise at least one of:
amorphous, nanocrystalline, microcrystalline, or polycrystalline silicon;
amorphous, nanocrystalline, microcrystalline, or polycrystalline silicon-germanium; or
amorphous, nanocrystalline, microcrystalline, or polycrystalline silicon-carbide.

16. The flexible ultraviolet light sensor of claim 12, wherein the solar cells comprise at least one of:
metal-oxide, organic, or perovskite semiconductor; or
copper zinc tin sulfide (CZTS); or
copper indium gallium diselenide (CIGS).

17. The flexible ultraviolet light sensor of claim 12, wherein the reflective display device comprises one of:
an electrophoretic display;
a cholesteric display; or
an electrowetting display.

18. The flexible ultraviolet light sensor of claim 12, wherein the floating gate transistor comprises one of:
amorphous silicon;
nano-crystalline silicon;
low-temperature poly-silicon (LTPS);
amorphous metal oxide;
organic, amorphous-silicon/LTPS heterojunction; or
organic/LTPS heterojunction.

19. The flexible ultraviolet light sensor of claim 12, wherein the solar cells are connected in series.

20. A method of detecting cumulative ultraviolet light exposure, the method comprising:
charging a floating gate in a floating gate transistor to reach a threshold voltage higher than the difference between a combined open circuit voltage of a number of solar cells and a switching threshold of a reflective display device, wherein the solar cells, reflective display device, and floating gate transistor are electrically connected to each other in a circuit; and
exposing the solar cells to ultraviolet light causing the floating gate to discharge, wherein when the threshold voltage drops below the difference between the combined open circuit voltage of the solar cells and the switching threshold of the reflective display device, thereby causing electrical current flow through the circuit, and wherein the reflective display device changes at least one of brightness or color as the electrical current flow increases, indicating total ultraviolet light exposure.
